(19) United States
(12) Patent Application Publication
(10) Pub. No.: US 2026/0168085 A1
(43) Pub. Date: Jun. 18, 2026

(54) METHOD AND SYSTEM FOR FILLING GAP

(71) Applicant: ASM IP Holding B.V., Almere (NL)

(72) Inventors: René Henricus Jozef Vervuurt, Leuven (BE); Patricio Eduardo Romero, Boutersem (BE); Viljami Pore, Helsinki (FI)

(21) Appl. No.: 19/419,481

(22) Filed: Dec. 15, 2025

Related U.S. Application Data
(60) Provisional application No. 63/734,776, filed on Dec. 17, 2024.
(60) Provisional application No. 63/739,805, filed on Dec. 30, 2024.

(51) Int. Cl. C23C 16/04; C23C 16/30; C23C 16/40; H10P 14/60

(52) U.S. Cl. CPC C23C 16/045; C23C 16/303; C23C 16/403; H10P 14/6336; H10P 14/6339

(57) ABSTRACT

A method for filling a gap includes providing a substrate in a reaction chamber, wherein the substrate comprises a gap. The method includes depositing a metal nitride layer having a first volume into the gap. The method includes converting the metal nitride layer into a metal oxide layer having a second volume. The second volume is greater than the first volume.

### CROSS-REFERENCE TO RELATED APPLICATIONS

The present application claims priority to and the benefit of U.S. Provisional Application No. 63/734,776, filed Dec. 17, 2024, and U.S. Provisional Application No. 63/739,805, filed Dec. 30, 2024. The entirety of each application is incorporated by reference herein.

### FIELD

The present disclosure relates to semiconductor technology, and in particular, to a method and a system for filling a gap.

### BACKGROUND

The scaling of semiconductor devices (such as logic devices and memory devices) has led to significant improvements in the speed and density of integrated circuits. However, conventional techniques for scaling-down the size of these devices face significant challenges for future technology nodes. One challenge has been to develop suitable methods for depositing thin-film materials that can fill substrate features without leaving gaps, voids, or seams. This is inherently challenging, particularly when using an ALD-like cyclic approach, which tends to produce conformal layers more readily.

Any discussion, including discussion of problems and solutions, set forth in this section has been included in this disclosure solely for the purpose of providing a context for the present disclosure. This discussion should not be taken as an admission that any or all of the information was known at the time the invention was made or otherwise constitutes prior art.

### BRIEF SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

One aspect of the present disclosure provides a method for filling a gap. The method includes providing a substrate in a reaction chamber. The substrate includes a gap. The method includes depositing a metal nitride layer having a first volume into the gap. The method further includes converting the metal nitride layer into a metal oxide layer having a second volume greater than the first volume.

In some embodiments, the metal nitride layer fills the gap substantially without seams.

In some embodiments, the second volume is greater than the first volume by 0.1-100%.

In some embodiments, before depositing the metal nitride layer, the method further comprises depositing a filling layer into the gap.

In some embodiments, the filling layer comprises a metal oxide.

In some embodiments, the step of converting the metal nitride layer into the metal oxide layer comprises a steam annealing process.

In some embodiments, the step of converting the metal nitride layer into the metal oxide layer comprises: a hydroxylation step that converts the metal nitride layer into a metal hydroxide layer; and a dehydration step that converts the metal hydroxide layer in to the metal oxide layer.

In some embodiments, the metal nitride layer comprises AlN, and the metal oxide layer comprises Al₂O₃.

In some embodiments, the metal hydroxide layer comprises AlO(OH)ₓ, Al(OH)ₓ, or a combination thereof, wherein x is a number ranging from 0 to 3.

In some embodiments, the steam annealing process is performed at a temperature ranging from 100° C. to 600° C. and for a duration time of about 30 minutes to about 200 minutes.

In some embodiments, the step of converting the metal nitride layer into the metal oxide layer comprises a treatment selected from at least one of ozone, hydrogen peroxide, oxygen plasma, oxygen radicals, or vacuum ultraviolet oxygen.

In some embodiments, the depositing a metal nitride layer into the gap comprises: performing a plasma enhanced atomic layer deposition (PEALD) process to conformally deposit the metal nitride layer on a bottom surface and sidewalls of the gap, wherein the plasma enhanced atomic layer deposition process comprises: providing a first precursor into the reaction chamber in vapor phase; and providing a treatment selected from at least one of NH₃ reactant, N₂ plasma, or N₂/H₂ plasma.

In some embodiments, the depositing a metal nitride layer into the gap comprises: performing a thermal atomic layer deposition (thermal ALD) process to conformally deposit the metal nitride layer on a bottom surface and sidewalls of the gap, wherein the thermal atomic layer deposition process comprises: providing a first precursor into the reaction chamber in vapor phase; and providing an NH₃ reactant into the reaction chamber.

In some embodiments, the depositing a metal nitride layer into the gap comprises providing a first precursor to the reaction chamber, wherein the first precursor comprises an organometallic compound; and providing a nitrogen-containing reactant to the reaction chamber.

In some embodiments, the metal in the organometallic compound comprises aluminum.

In some embodiments, the organometallic compound comprises an ethyl or a methyl group.

In some embodiments, the first precursor comprises trimethylaluminum or triethylaluminum.

Another aspect of the present disclosure provides a system for filling a gap. The system includes a reaction chamber, a heater, a precursor source, a nitrogen-containing reactant source, an oxygen-containing reactant source, and a controller. The reaction chamber includes a substrate support for supporting a substrate. The heater is constructed and arranged to heat the substrate in the reaction chamber. The precursor source containing a precursor is coupled to the reaction chamber. The nitrogen-containing reactant source containing a nitrogen-containing reactant is coupled to the reaction chamber. The oxygen-containing reactant source containing an oxygen-containing reactant is coupled to the reaction chamber. In some embodiments, a plasma source configured to generate plasma is connected to the reaction chamber. The controller is programmed and/or configured to control the precursor source, nitrogen-containing reactant source, and the oxygen-containing species source into the reaction chamber, to deposit a metal nitride layer, and to convert the metal nitride layer into a metal oxide layer by a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWINGS

The present invention can be more fully understood by reading the subsequent detailed description and examples with references made to the accompanying drawings, wherein:

FIG. 1 is a flowchart of a method for filling a gap on a substrate according to an embodiment of the present disclosure;

FIG. 2 is a flowchart of a cyclic process for forming a layer on a substrate according to an embodiment of the present disclosure;

FIGS. 3-5 are each schematic views of structures according to embodiments of the present disclosure;

FIG. 6 is a flowchart of a method for filling a gap on a substrate according to an embodiment of the present disclosure;

FIGS. 7 and 8 are each schematic views of structures according to embodiments of the present disclosure; and

FIG. 9 is a schematic view of a system according to an embodiment of the present disclosure.

### DETAILED DESCRIPTION

The following description is made for the purpose of illustrating the general principles of the disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. Further, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

As used herein, the term “precursor” can refer to a compound that participates in the chemical reaction that produces another compound. In this disclosure, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, gaps, voids, seams, and the like formed within or on at least a portion of the substrate. By way of example, a substrate can include at least one of bulk semiconductor material and an insulating or dielectric material layer overlying at least a portion of the bulk semiconductor material.

As used herein, the term “film” or “layer” can refer to any continuous or non-continuous structure and material, such as material deposited by a method as disclosed herein. For example, a film or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may include material or a layer with pinholes and/or isolated islands. A film or layer may be at least partially continuous. A film or layer may be patterned, e.g., subdivided, and may be included in a plurality of semiconductor devices.

In this disclosure, the term “deposition process” as used herein can refer to the introduction of one or more precursors into a reaction chamber to deposit a layer over a substrate. The term “cyclical deposition process” can refer to a sequential introduction of precursors into a reaction chamber to deposit a layer or a film over a substrate and includes processing techniques such as atomic layer deposition (ALD), cyclical chemical vapor deposition (cyclical CVD), and hybrid cyclical deposition processes that include an ALD and a CVD.

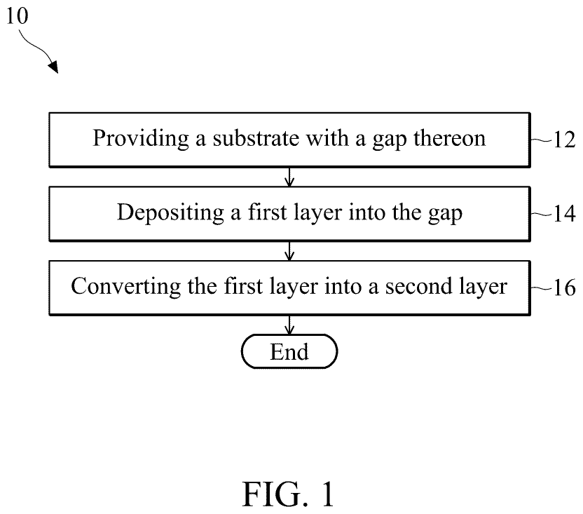

In general, the disclosure is directed to a technology utilizing volume expansion for gap filling. One aspect of the present disclosure is providing a method for filling a gap in the substrate. FIG. 1 is a flowchart of a method for filling a gap on a substrate according to an embodiment of the present disclosure. As shown in FIG. 1, method 10 includes step 12 of providing a substrate with a gap thereon; step 14 of depositing a first layer into the gap; and step 16 of converting the first layer into a second layer (e.g., by performing a conversion process).

It should be understood that method 10 illustrated in FIG. 1 is merely exemplary and is not intended to limit the present disclosure. Additional steps may be provided before, during, and after method 10 or the steps shown. For example, in some embodiments, step 13 of depositing a filling layer into the gap may be implemented before step 14 of depositing a first layer into the gap, as will be described in detail later in FIG. 5.

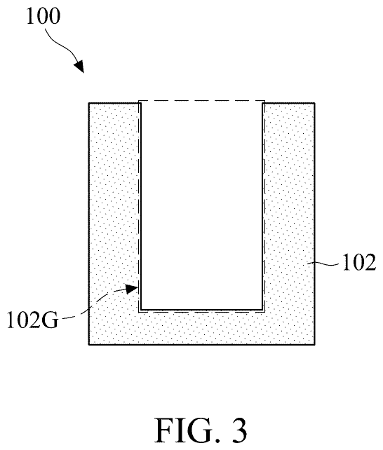

Please refer to FIGS. 1 and 3. FIG. 3 is a schematic view of a structure corresponding to step 12 in FIG. 1. As shown in FIG. 3, step 12 provides a substrate 102 with a gap 102G on the surface in a reaction chamber. The substrate 102 may include any suitable materials. In some embodiments, the substrate 102 may include a monocrystalline silicon wafer, monocrystalline germanium wafers, gallium arsenide wafers, quartz, sapphire, glass, steel, aluminum, silicon-on-insulator substrates, plastics, and the like, but the disclosure is not limited thereto. The term “substrate” is meant to include features formed within a semiconductor wafer and layers overlying the wafer. The term “substrate surface” is meant to include the uppermost exposed layers on a semiconductor wafer, such as a silicon surface, fin structures, isolation features, epitaxial source/drain features, and nanostructures of the GAA (gate-all-around) transistor. In some embodiments, the gap 102G on the substrate 102 may be a void, a seam, or a combination thereof, and the method of the present disclosure may be useful for filling the gap, the void, or the seam. For simplicity of illustration, only one gap 102G is illustrated on substrate 102 in FIG. 3 and the term “gap 102G” may be used to refer to one or more gaps, voids, or seams. Thus, it may be understood that substrate 102 may include any suitable number of gap 102G, and each gap 102G may be a void, a seam, or a combination thereof in the embodiments of the present disclosure.

In some embodiments, the gap 102G in the substrate 102 may have a depth of at least 5 nm to at most 500 nm, a width of at least 10 nm to at most 10,000 nm, and/or a length of at least 10 nm to at most 10,000 nm. In some embodiments, the gap 102G in the substrate 102 may have a depth of at least 10 nm to at most 250 nm, or from at least 20 nm to at most 200 nm, or from at least 50 nm to at most 150 nm, or from at least 100 nm to at most 150 nm. In some embodiments, the gap 102G in the substrate may have a width of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm. In some embodiments, the gap 102G in the substrate may have a length of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm.

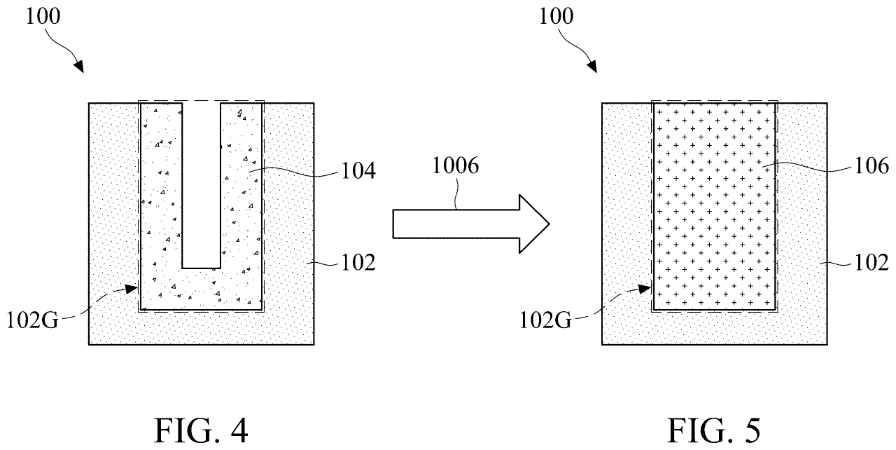

FIG. 4 is schematic view of a structure corresponding to step 14 in FIG. 1. As shown in FIG. 4, step 14 fills the gap 102G with a first layer 104. In some embodiments, the first layer 104 may comprise a metal nitride layer, such as aluminum nitride (AlN), which may be converted into a metal oxide layer having a greater volume in a conversion process (e.g., oxidization process). In some embodiments, filling the gap 102G with the first layer 104 includes performing a cyclic process, such as a plasma enhanced atomic layer deposition process or a thermal atomic layer deposition process, to form the first layer 104 on the substrate 102.

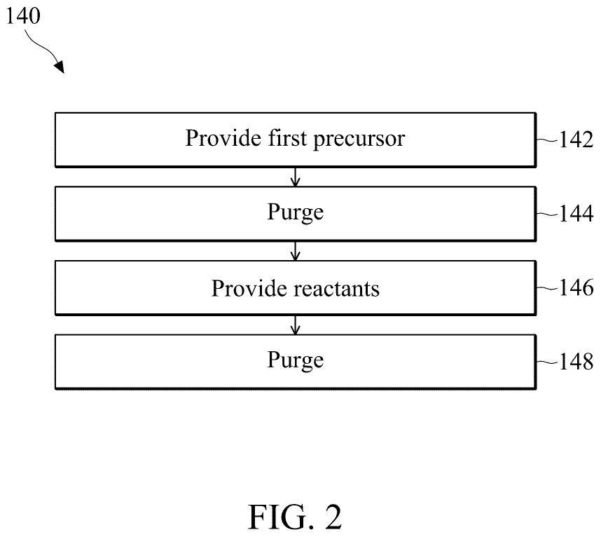

FIG. 2 is a flowchart of a cyclic process for forming the first layer 104 on a substrate 102 according to an embodiment of the present disclosure. In particular, FIG. 2 illustrates a process for forming the first layer 104 in step 14. In some embodiments, forming the first layer 104 includes a cyclic process 140 as illustrated in FIG. 2. As shown in FIG. 2, the cyclic process 140 includes a step 142 of providing the first precursor to the reaction chamber; a step 144 of purging the reaction chamber; a step 146 of providing an agent and/or reactant to the reaction chamber; and a step 148 of purging the reaction chamber.

In step 142, substrate 102 is first positioned on a substrate support. The substrate support is positioned in a reaction chamber. Suitable substrate supports include pedestals, susceptors, and the like. Then, a first precursor is provided into the reaction chamber. In some embodiments, the first precursor comprises a transition metal, such as titanium, tantalum, tungsten, tin, hafnium, or a combination thereof. In some embodiments, the precursor containing a metal may include a metal halide or a metal-organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halides, or other metal-containing compounds. In some embodiments where the first layer 104 comprises aluminum nitride (AlN), the first precursor comprises an aluminum-based precursor, such as trimethylaluminum (TMA) or triethylaluminium (TEA). In some embodiments, the first precursor may be provided by pulsing into the reaction chamber. In some embodiments, the pulse time may be between 0.01 and 5 seconds.

Optionally, the reaction chamber is then purged as step 144 before proceeding to step 146. Purging may be done by exposing substrate 102 to one or more purge gases in turn, for example, by providing one or more purge gases to the reaction chamber. Exemplary purge gasses include noble gases. Noble gases include He, Ne, Ar, Xe, and Kr.

In step 146, one or more nitriding reactants (e.g., nitrogen-containing reactants) may be introduced to the reaction chamber. Exemplary nitriding reactants include ammonia (NH₃). In some embodiments, the first layer 104 is formed by a plasma enhanced atomic layer deposition (PEALD) process. In a PEALD process, a reactive species generated from a plasma produced from a reactant gas is provided into the reaction chamber. In some embodiments, the reactant gas is selected from at least one of ammonia (NH₃), ammonia plasma, nitrogen/hydrogen (N₂/H₂) plasma, nitrogen (N₂) plasma, or nitrogen radicals. In some embodiments, the first layer 104 is formed by a thermal atomic layer deposition (tALD) process. In a tALD process, a reactant gas is provided into the reaction chamber. In some embodiments, the reactant gas may include ammonia (NH₃), nitrogen (N₂) or nitrogen/hydrogen (N₂/H₂). Optionally, the reaction chamber is then purged in step 148. In some embodiments, purging in step 148 may be similar to the purging of step 144.

In some embodiments, the cyclic process including step 142, step 144, step 146, and step 148 may be performed one or more times until a sufficient amount of the first layer 104 is deposited in the gap 102G. Furthermore, in a cyclic process, each of the step 142 and step 146 may be performed one or more times. Since the first layer 104 will later be converted into a second layer 106 with a greater volume, the first layer does not need to completely fill the gap 102G. In some embodiments, depending on the expansion ratio of the first layer during the conversion step, only 20-70% of the volume of the gap may need to be filled. In some embodiments, the first layer 104 may be deposited conformally in the gap 102G, as illustrated in FIG. 4. In other words, the first layer 104 may have a thickness that is constant over the bottom surface and sidewalls of the gap 102G, e.g., within a margin of error of 50%, 20%, 10%, 5%, 2%, 1%, 0.5%, or 0.1%.

In some embodiments, the temperature within the reaction chamber during step 14 of depositing a first layer 104 into the gap 102G may less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C.

In some embodiments, the pressure inside the reaction chamber during step 14 of depositing a first layer into the gap may less than 760 Torr or of at least 0.2 Torr to at most 760 Torr, of at least 1 Torr to at most 100 Torr, or of at least 1 Torr to at most 10 Torr. In some embodiments, step 14 of depositing a first layer into the gap may be performed at most 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at most 10⁻² Torr, or at a pressure of at most 10⁻³ Torr, or at a pressure of at most 10⁻⁴ Torr, or at a pressure of at most 10⁻⁵ Torr, or at a pressure of at least 0.1 Torr to at most 10 Torr, or at a pressure of at least 0.2 Torr to at most 5 Torr, or at a pressure of at least 0.5 Torr to at most 2.0 Torr.

Referring to FIGS. 1 and 5, FIG. 5 is a schematic view of a structure corresponding to step 16 in FIG. 1. In some embodiments, once the first layer 104 is formed in the gap 102G, a conversion process as described in step 16 may be performed to convert the first layer 104 into a second layer 106. In some embodiments, the second layer 106 is a metal oxide layer. In a specific embodiment, the first layer 104 is an aluminum nitride (AlN) layer and the second layer 106 is an aluminum oxide (Al₂O₃) layer.

In some embodiments, the conversion process is performed by an oxidizing treatment. For example, the conversion process in step 16 may be a steam annealing process in some embodiments. Alternatively, the conversion process in step 16 comprise a process that includes a treatment selected from at least one of ozone, hydrogen peroxide, oxygen plasma, oxygen radicals, or vacuum ultraviolet oxygen. In some embodiments, the conversion process in step 16 converts the first layer 104 from a metal nitride layer into a metal oxide layer. In some embodiments, the first layer 104 is an aluminum nitride (AlN) layer and is converted (e.g., oxidized) into an aluminum oxide (Al₂O₃) layer by the conversion process in step 16.

In embodiments where the first layer 104 is an aluminum nitride (AlN) layer and the conversion process is a steam annealing process, the steam annealing process may include a hydroxylation step followed by a dehydration step. In some embodiments, the hydroxylation step converts the first layer 104 from a metal nitride layer into a metal hydroxide layer as an intermediate layer. In some embodiments, the hydroxylation step converts the aluminum nitride (AlN) layer 104 into an aluminum hydroxide layer. In some embodiments, the aluminum hydroxide layer comprise AlO(OH)ₓ, Al(OH)ₓ, or a combination thereof as intermediate(s). In some embodiments, x is a number ranging from 0 to 3. In some embodiments, an intermediate aluminum hydroxide layer is converted to an aluminum oxide (Al₂O₃) layer by a subsequent dehydration step.

In some embodiments, the steam annealing process may be performed at a temperature ranging from 100° C. to 600° C. for a duration of about 30 minutes to about 200 minutes. In some embodiments, the steam annealing process may be performed under a pressure of around 750 Torr. However, this disclosure is not limited to these conditions. The temperature and the pressure of steam annealing may be adjusted depending on the amount of the first layer 104 expected to be converted into the second layer 106.

Referring again to FIGS. 1 and 5, by the conversion process in step 16, the first layer 104 is converted into the second layer 106 (e.g., the aluminum nitride is converted into aluminum oxide) and expands to substantially fill the gap 102G without an additional deposition process (FIG. 5). That is, the first layer 104 has a first volume and the converted second layer 106 has a second volume greater than the first volume. In some embodiments, the second volume of the second layer 106 may be 0.1-100% greater than the first volume of the first layer. In some embodiments, the second volume of the second layer may be at least 1% greater, 5% greater, 10% greater, 25% greater, 50% greater, 75% greater, 90% greater, 95% greater than the first volume of the first layer 104. In some embodiments, the second volume of the second layer 106 may be 25-99% greater or 50-95% greater than the first volume of the first layer 104. However, this disclosure is not limited hereto. Herein, the volume of a given layer is defined by the total volume of the layer filling the gap 102G.

In some embodiments, the volume expansion during the conversion from a metal nitride material to a metal oxide material may be attributed to unit cell, density, spatial arrangement, or any other factor that could lead to volume expansion. By adopting a method that fills a gap by converting a deposited metal nitride material, e.g., aluminum nitride (AlN), into a metal oxide material, e.g., aluminum oxide (Al₂O₃), aluminum oxide (Al₂O₃), fills the gap more thoroughly due to its larger volume. As a result, the gap 102G may be filled substantially without voids or seams by replacing a portion or the entire aluminum oxide (Al₂O₃) with aluminum nitride (AlN) in the gap and then converting the aluminum nitride (AlN) into aluminum oxide (Al₂O₃). The term “the gap is filled substantially without voids or seams” as used herein refers to a gap without voids having a size of approximately 5 nm or greater in diameter, or seams having a length of approximately 5 nm or greater.

In some embodiments of the present disclosure, the resulting volume expansion rate by the conversion of aluminum nitride (AlN) into aluminum oxide (Al₂O₃) may be controlled by controlling the parameters of the oxidizing treatment as described in step 16 (e.g., processing time). In some embodiments, an appropriate processing time of the oxidizing treatment may be set according to the desired expansion rate, thereby filling the gap 102G of a specific size. In other words, the processing time of the oxidizing treatment may be set according to the size of the gap 102G in the embodiments of the present disclosure. Experiments demonstrate that converting aluminum nitride (AlN) into aluminum oxide (Al₂O₃) through a steam annealing treatment as described in step 16, performed under 500° C. and for about 75 minutes, may result in a volume expansion of about 90%. However, the expansion rate does not increase indefinitely with longer processing times for the oxidizing treatment. Instead, the expansion rate reaches saturation as the processing time extends beyond a certain point. This occurs because most of the aluminum nitride (AlN) is substantially converted into aluminum oxide (Al₂O₃) after a certain duration, resulting in no significant volume expansion even with further increases in processing time.

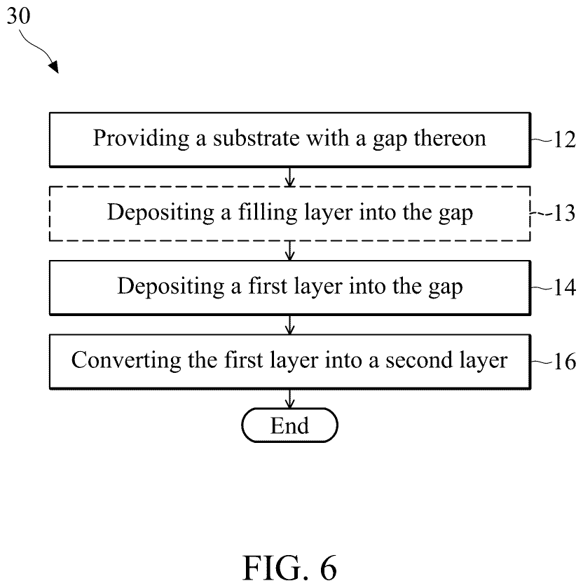

FIG. 6 is a flowchart of a method for filling a gap on a substrate according to other embodiments of the present disclosure having the additional steps described below. The method 30 illustrated in FIG. 6 may be similar to method 10 illustrated in FIG. 1, except for the additional step 13 of depositing a filling layer 103 into gap 102G before depositing a first layer 104 into gap 102G. In some embodiments, the filling layer comprises the same material as the second layer. In such an embodiment, a portion of the second layer 106 is directly deposited as a filling layer 103 in the gap 102G, while another portion of the second layer 106 is converted from the first layer 104.

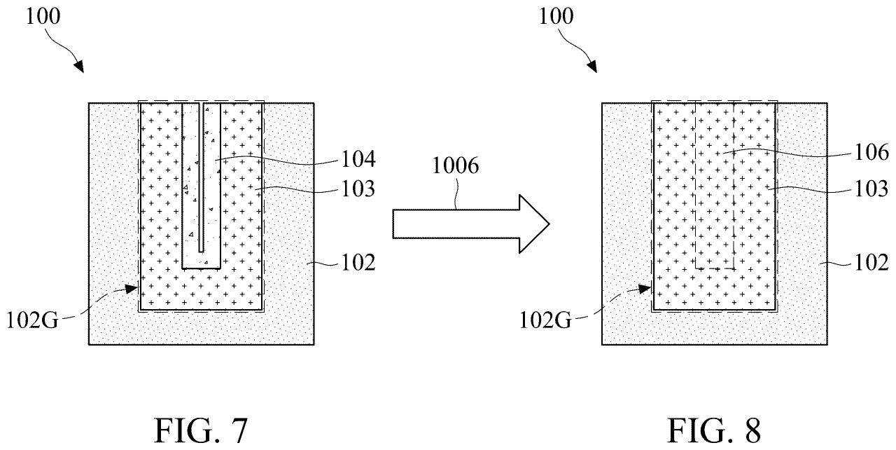

FIGS. 7 and 8 are schematic views of structures corresponding to steps 13-16 of FIG. 6. As shown in FIG. 7, the gap 102G is first filled with the filling layer 103, and then filled with the first layer 104, followed by converting the first layer 104 into the second layer 106 in some embodiments. In some embodiments, filling the gap 102G with the filling layer 103 in step 13 may be similar to a method of forming the first layer 104 in step 14 (e.g., as the cyclic process illustrated in FIG. 2), except for some adjustments. For example, in embodiments where the first layer 104 includes aluminum nitride (AlN) and the filling layer 103 includes aluminum oxide (Al₂O₃), the filling layer 103 may be formed by the cyclic process in FIG. 2 while providing an oxidizing agent (e.g., oxygen (O₂), water (H₂O), ozone (O₃), and/or hydrogen peroxide (H₂O₂)) in step 146 to construct an oxidized environment. Once the filling layer 103 is formed with step 13, the first layer 104 is subsequently formed on the filling layer 103 and converted to the second layer 106, as illustrated in FIG. 8. Although a dashed line is depicted in FIG. 8 to represent the interface between the second layer 106 and the filling layer 103, there may be no distinct interface when the two layers are made of the same material.

In some embodiments, step 13 may be performed to expedite the overall gap-filling process to increase throughput. However, filling the gap 102G with too much filling layer 103 also makes the opening in gap 102G too small to form the first layer 104. In some embodiments, step 13 may fill about 70% to 90% of the volume in the gap 102G with the filling layer 103. In some embodiments, step 13 fills about 80% of the volume in the gap 102G with the filling layer 103.

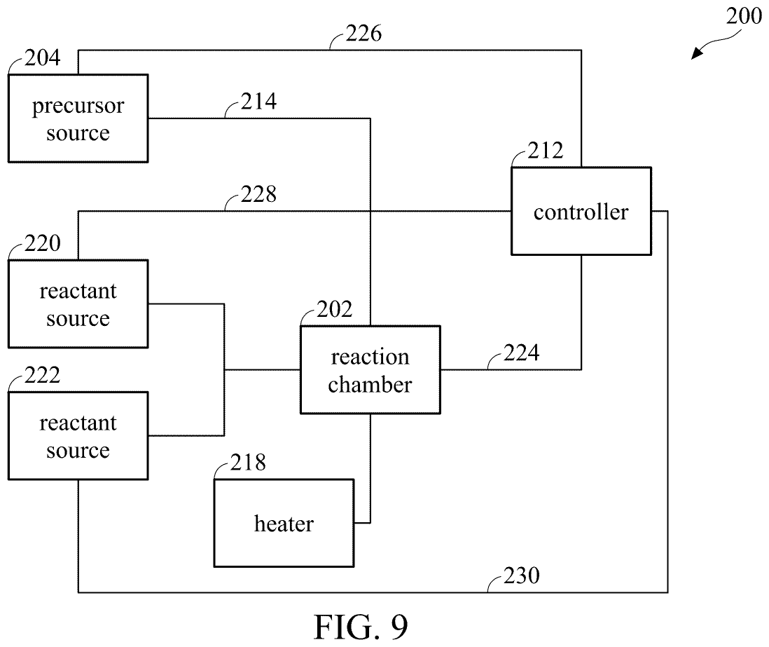

Another aspect of the present disclosure provides a system for filling a gap. In this regard, FIG. 9 is a schematic view of a system according to an embodiment of the present disclosure. The system 200 illustrated in FIG. 9 may be used to perform a method as described herein and/or to form a structure or a device, or a portion thereof as described herein.

As shown in FIG. 9, in some embodiments, the system 200 includes one or more reaction chambers 202, heaters 218, a precursor source 204, a first reactant source 220, a second reactant source 222, and a controller 212. In some embodiments, the system 200 may include one or more additional gas sources (not shown), such as a reactant source, an inert gas source, a carrier gas source, a plasma source and/or a purge gas source.

In some embodiments, the reaction chamber 202 may include any suitable reaction chamber, such as a PEALD, ALD, PECVD or CVD reaction chamber. In some embodiments, reaction chamber 202 may include one or more substrate supports for supporting substrates. In some embodiments, a heater 218 may be constructed and arranged to provide heat into the reaction chamber. The heater 218 is configured to heat the substrate in the reaction chamber 202 to an elevated temperature required for the processing requirements. For example, the heater 218 can be a radiative heater, such as a lamp, or a resistive heater.

In some embodiments, the precursor source 204 may be a vessel including one or more precursors as described herein alone or mixed with one or more carrier (e.g., inert) gases. Although illustrated with one precursor source 204, the system 200 may include any suitable number of precursor sources in embodiments of the present disclosure. The precursor source 204 may be coupled to the reaction chamber 202 via lines 214, which may each include flow controllers, valves, heaters, and the like. In some embodiments, the precursor source 204 may be heated. In some embodiments, a vessel as the precursor source 204 is heated so that a precursor reaches a temperature between, for example, about 30° C. to about 200° C., depending on the properties of the chemical in question.

In some embodiments, the first reactant source 220 and the second reactant source 222 may each be coupled to the reaction chamber 202 to provide the reactants required for specific reactions. In this disclosure, the first reactant source 220 is a nitrogen-containing reactant source and the second reactant source 222 is an oxygen-containing reactant source.

In some embodiments, the plasma source may be a capacitively coupled plasma source, an inductively coupled plasma source, a microwave plasma source or electron cyclotron resonance plasma source.

In some embodiments, the controller 212 includes electronic circuitry and software to selectively operate injectors, valves, manifolds, heaters, pumps, and other components included in the system 200. Such circuitry and components operate to introduce precursors, reactants, and purge gases from the respective sources. The controller 212 may be programmed and/or configured to control the timing of gas pulse sequences, the temperature of the substrate or reaction chamber 202, and the pressure inside the reaction chamber 202, through a wired or wireless link 224. The controller 212 may include control software to electrically or pneumatically control valves to control the flow of precursors, and reactants, and purge gases into and out of the reaction chamber 202. In some embodiments, the controller 212 may also be configured to control the operation of the precursor source 204, the first reactant source 220, and the second reactant source 222 through wired or wireless links 226, 228, and 230 to facilitate each operation of the system 200. For example, the controller 212 controls and coordinates the precursor source 204, the first reactant source 220, and the second reactant source 222 to execute the steps such as depositing the first layer 104 and converting the first layer into a second layer as described above. The controller 212 may include modules, such as a software or hardware component, which performs certain tasks. Such a module may be configured to reside on the addressable storage medium of the control system and be programmed and/or configured to execute one or more processes as described herein.

Other configurations of the system 200 are possible, including different numbers and kinds of precursor and reactant sources. Further, it will be appreciated that there are many arrangements of valves, conduits, precursor sources, and auxiliary reactant sources that may be used to accomplish the goal of selectively and in a coordinated manner feeding gases into reaction chamber 202. Further, as a schematic representation of a deposition assembly, many components have been omitted for simplicity of illustration, and such components may include, for example, various injectors, valves, manifolds, purifiers, heaters, containers, vents, and/or bypasses.

The system may be used to perform the method of the present disclosure which may provide a substrate without gaps, voids, or seams. The system may be advantageously used in the field of integrated circuit manufacture.

Although embodiments of the present disclosure and the advantages thereof have been disclosed as described above, it should be understood that changes, substitutions, and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

1. A method for filling a gap, comprising:
providing a substrate in a reaction chamber, wherein the substrate comprises a gap;
depositing a metal nitride layer having a first volume into the gap; and
converting the metal nitride layer into a metal oxide layer having a second volume greater than the first volume.

2. The method of claim 1, wherein the metal nitride layer fills the gap substantially without seams.

3. The method of claim 1, wherein the second volume is greater than the first volume by 0.1-100%.

4. The method of claim 1, wherein before depositing the metal nitride layer, the method further comprises depositing a filling layer into the gap.

5. The method of claim 4, wherein the filling layer comprises a metal oxide.

6. The method of claim 1, wherein the step of converting the metal nitride layer into the metal oxide layer comprises a steam annealing process.

7. The method of claim 6, wherein the step of converting the metal nitride layer into the metal oxide layer comprises:
a hydroxylation step that converts the metal nitride layer into a metal hydroxide layer; and
a dehydration step that converts the metal hydroxide layer in to the metal oxide layer.

8. The method of claim 7, wherein the metal nitride layer comprises AlN, and wherein the metal oxide layer comprises Al₂O₃.

9. The method of claim 7, wherein the metal hydroxide layer comprises AlO(OH)ₓ, Al(OH)ₓ, or a combination thereof, wherein x is a number ranging from 0 to 3.

10. The method of claim 6, wherein the steam annealing process is performed at a temperature ranging from 100° C. to 600° C. and for a duration time of about 30 minutes to about 200 minutes.

11. The method of claim 1, wherein the step of converting the metal nitride layer into the metal oxide layer comprises a treatment selected from at least one of ozone, hydrogen peroxide, oxygen plasma, oxygen radicals, or vacuum ultraviolet oxygen.

12. The method of claim 1, wherein the depositing a metal nitride layer into the gap comprises:
performing a plasma enhanced atomic layer deposition (PEALD) process to conformally deposit the metal nitride layer on a bottom surface and sidewalls of the gap, wherein the plasma enhanced atomic layer deposition process comprises:
providing a first precursor into the reaction chamber in vapor phase; and
providing a treatment selected from at least one of NH₃ reactant, N₂ plasma, or N₂/H₂ plasma.

13. The method of claim 1, wherein the depositing a metal nitride layer into the gap comprises:
performing a thermal atomic layer deposition (thermal ALD) process to conformally deposit the metal nitride layer on a bottom surface and sidewalls of the gap, wherein the thermal atomic layer deposition process comprises:
providing a first precursor into the reaction chamber in vapor phase; and
providing an NH₃ reactant into the reaction chamber.

14. The method of claim 12, wherein depositing a metal nitride layer into the gap comprises: providing a first precursor to the reaction chamber, wherein the first precursor comprises an organometallic compound; and providing a nitrogen-containing reactant to the reaction chamber.

15. The method of claim 14, wherein the metal in the organometallic compound comprises aluminum.

16. The method of claim 14, wherein the organometallic compound comprises an ethyl or a methyl group.

17. The method of claim 14, wherein the first precursor comprises trimethylaluminum or triethylaluminum.

18. A system, comprising:
a reaction chamber comprising a substrate support for supporting a substrate;
a heater constructed and arranged to heat the substrate in the reaction chamber;
a precursor source containing a precursor coupled to the reaction chamber;
a nitrogen-containing reactant source containing a nitrogen-containing reactant coupled to the reaction chamber;
an oxygen-containing reactant source containing an oxygen-containing reactant coupled to the reaction chamber;
a plasma source configured to generate plasma connected to the reaction chamber; and
a controller configured to control the precursor source, nitrogen-containing reactant source, and the oxygen-containing reactant source into the reaction chamber, to deposit a metal nitride layer, and to convert the metal nitride layer into a metal oxide layer by the method according to claim 1.
